(19) United States
(12) Patent Application Publication
(10) Pub. No.: US 2012/0248455 A1
(43) Pub. Date: Oct. 4, 2012

(54) PROCESS FOR MANUFACTURING A CRYSTALLINE SILICON LAYER

(75) Inventor: Dries Van Gestel, Vosselaar (BE)

(73) Assignees: Katholieke Universiteit Leuven, Leuven (BE); IMEC, Leuven (BE)

(21) Appl. No.: 13/410,133

(22) Filed: Mar. 1, 2012

Related U.S. Application Data
(63) Continuation of application No. PCT/EP2010/062905, filed on Sep. 2, 2010.
(60) Provisional application No. 61/275,840, filed on Sep. 2, 2009.

(51) Int. Cl. H01L 21/20; H01L 29/04

(52) U.S. Cl. 257/75; 438/486; 257/E21.133; 257/E29.003

(57) ABSTRACT

A method of forming a crystalline silicon layer on a substrate is disclosed. In one aspect, the method includes performing a metal induced crystallization process. The process includes depositing a metal (e.g. aluminum) on the substrate at a first temperature, the metal having an external surface. The method may also include oxidizing the external surface of the metal at a second temperature, and depositing amorphous silicon on the oxidized external surface of the metal at a third temperature. The method may also include annealing the metal and the silicon at a fourth temperature, whereby a crystalline silicon layer is obtained on the substrate covered by an external layer comprising the metal, and removing the external layer comprising the metal thereby exposing the crystalline silicon layer, wherein at least the first temperature and the fourth temperature (crystallization temperature) are not lower than 200° C.

### CROSS REFERENCE TO RELATED APPLICATIONS

This application is a continuation of PCT Application No. PCT/EP2010/062905, filed Sep. 2, 2010, which claims priority under 35 U.S.C. §119(e) to U.S. provisional patent application 61/275,840 filed on Sep. 2, 2009. Each of the above applications is incorporated herein by reference in its entirety.

### BACKGROUND OF THE INVENTION

1. Field of the Invention

The disclosed technology relates to a process for manufacturing a crystalline silicon layer on a substrate via a metal induced crystallization process and to the application of the process in manufacturing electronic devices such as photovoltaic cells.

2. Description of the Related Technology

Thin-film crystalline silicon photovoltaic cells on cheap foreign (non-silicon) substrates are a promising alternative to traditional bulk crystalline silicon photovoltaic cells because of their higher potential for cost reduction. However, most of the approaches for realizing such thin film cells have led to devices with much lower energy conversion efficiency than traditional photovoltaic cells. A major reason is the lower crystallographic quality of the silicon layers, e.g. obtained by deposition and/or crystallization, on the cheap foreign substrates.

One approach to crystallization is based on metal-induced crystallization (MIC). This crystallization process allows creating thin polycrystalline layers on foreign substrates. For applications in photovoltaic cells the MIC process is typically followed by epitaxial deposition. One particular example of MIC is aluminum induced crystallization (AIC). The polycrystalline silicon layer resulting from a MIC process can be used as a seed layer for epitaxial growth. An additional layer can be deposited epitaxially on the seed layer, reproducing the grain structure of the seed layer in the epitaxial layer. In a photovoltaic cell, this epitaxial layer may be used as the active layer wherein light is converted into electricity.

If the epitaxial process is done at low temperatures (e.g. by using ECR PECVD or Ion-assisted deposition), low-cost glass can be used as a substrate. In the context of photovoltaic cell manufacturing, the use of glass substrates could lead to very low cost cells. However, low temperature epitaxy on imperfect surfaces presents a serious technological challenge.

Alternatively, the epitaxial growth can be done with a high temperature technique (e.g. thermal chemical vapor deposition). Using a high temperature technique has advantages (good epitaxial quality with a simple process), but also imposes restrictions on the foreign substrates that can be used. Standard low-cost glass cannot be used because it cannot withstand high temperatures. Therefore ceramic substrates are often considered for the high temperature route. Aluminum-induced crystallization directly on ceramic substrates however results in an average grain size that is low (e.g., about 1 to 2 micron), and a high density of islands.

US 2006/0030132A1 discloses a wafer for use in a solar cell, comprising: a substrate comprising a microrough face; a dielectric layer formed on the microrough face, wherein the surface of the dielectric after deposition is less microrough than the microrough face; and a crystalline silicon layer formed on the dielectric; and a method of forming a crystalline silicon layer on a face of a substrate, the face being microrough prior to forming the layer, comprising: reducing the amount of the microroughness on the face; and performing a metal induced crystallization process on the face. It is shown that larger grain sizes can be obtained if the microroughness of the ceramic substrate is reduced before starting the AIC process. Reducing the microroughness can for example be performed by providing a microflattening layer such as for example a flowable oxide (FOx) layer on the substrate surface before depositing an aluminum layer. Aluminum deposition is performed by electron beam evaporation, which gives a coating temperature at ca.40° C. as shown in 2005 by A Jankowski et al. in Thin Solid Films, volume 291, pages 61-65. Silicon evaporation is either performed by electron beam evaporation or by decomposition of silane at 400° C. Annealing is carried out at 500° C.

The presence of secondary crystallites and/or islands on the seed layer may have a negative effect on the quality of the layer that is grown epitaxially on top of the seed layer. Therefore, a better epitaxial quality may be obtained if the secondary crystallites and/or islands are removed before epitaxial growth. Methods for removing secondary crystallites and/or island are for example described in patent applications WO 2004/033769 and in US 2008/0268622A1 which discloses a method for forming a crystalline silicon layer on a face of a substrate, wherein the face is microrough prior to forming the crystalline silicon layer, comprising: reducing an amount of microroughness on a microrough face of a substrate, whereby a microflattened face is obtained; performing a metal induced crystallization process on the microflattened face of the substrate by depositing a metal, oxidizing the metal, depositing silicon on the metal and annealing the metal and the silicon, whereby a crystalline silicon layer is obtained on the microflattened face and whereby a metal layer is obtained on the crystalline silicon layer, the metal layer comprising secondary crystallites and silicon islands; removing the silicon islands, thereby using the metal layer as a mask; and removing the metal layer.

In order to obtain good conversion efficiencies for photovoltaic cells that are based on epitaxial thickening of seed layers formed by AIC, there is a need for a good crystalline quality of the epitaxial layer. Therefore, a lot of effort has been devoted to increasing the grain size of the AIC seed layers. The larger the grain size, the lower the number of grain boundaries and thus the lower the number of defects associated with the grain boundaries and serving as charge carrier recombination centers. Therefore, it can be expected that larger grains lead to a larger open circuit voltage (V_{oc}) of the photovoltaic cells. However, as reported by D. Van Gestel et al in “Influence of seed layer morphology on the epitaxial growth of polycrystalline silicon solar cells”, Thin Solid Films 511-512 (2006), pp 35-40, the open-circuit voltage of this type of cells is quasi-independent on the grain size. In “Electrical activity of intra-grain defects in polycrystalline silicon layers obtained by aluminum-induced crystallization and epitaxy”, D. Van Gestel et al., Applied Physics Letters 90, 092103 (2007), a very large density of intra-grain defects in polycrystalline silicon layers obtained through aluminum induced crystallization of amorphous silicon and epitaxy is reported.

Electron-beam-induced current measurements show a strong recombination activity at these defects. These results indicate that the unexpected quasi-independence on the grain size of the open-circuit voltage of photovoltaic cells may be related to the presence of a high density of electrically active intra-grain defects. It was estimated that most intra-grain defects are formed in the seed layer or at the interface between the seed layer and the epitaxial layer.

Therefore, to improve the AIC seed layer quality and the quality of the epitaxial layer, and thus to improve the photovoltaic cell performance, there is a need for reducing the intra-grain defect density and/or making the intra-grain defects electrically inactive.

### SUMMARY OF CERTAIN INVENTIVE ASPECTS

Certain inventive aspects relate to a process for reducing the intra-grain defect density and/or making the intra-grain defects electrically inactive.

It is an advantage that the stress resulting from a difference in expansion coefficient CTE between the different layers and the substrate with a change in temperature can be avoided or substantially reduced.

It is an advantage of certain inventive aspects that seed layers e.g. silicon seed layers resulting from metal induced crystallization (MIC), e.g., aluminum-induced crystallization (AIC) are realized with a substantially, e.g., a factor of at least about 2, lower density of electrically active intra-grain defects.

Certain inventive aspects relate to a method for forming good seed layers based on metal induced crystallization (MIC), e.g. aluminum induced crystallization (AIC), wherein the seed layers have an intra-grain defect density that is substantially, e.g. a factor of about 2 or more, lower than the intra-grain defect density of prior art MIC based seed layers. MIC based seed layers according to one inventive embodiment enables the epitaxial growth of a polycrystalline silicon layer on the seed layer, wherein the density of intra-grain defects in the polycrystalline silicon layer is substantially, e.g. a factor of about 2 or more, lower than that for epitaxial layers grown on prior art MIC-based (e.g. AIC based) seed layers.

Certain inventive aspects relate to a method comprising forming on a substrate forming a metal layer, e.g. an aluminum layer, at a first temperature; oxidizing the metal layer, e.g. aluminum layer, at a second temperature; depositing an amorphous silicon layer on the oxidized metal layer, e.g. oxidized aluminum layer, at a third temperature; and performing an annealing step at a fourth temperature or crystallization temperature for realizing metal induced crystallization, e.g. aluminum induced crystallization, wherein at least the first temperature and the fourth temperature (crystallization temperature) are not lower than 200° C. This method results in a seed layer with an intra-grain defect density that is substantially (e.g. at least a factor of 2) lower than the defect density of prior art seed layers, allowing epitaxial growth of a polycrystalline silicon layer on the seed layer, wherein the density of intra-grain defects in the polycrystalline silicon layer is substantially (e.g. at least a factor of 2) lower than the density of intra-grain defects in epitaxial layers grown on prior art MIC-based (e.g. AIC-based) seed layers. This allows epitaxial growth of a polycrystalline silicon layer on the seed layers, wherein the density of intragrain defects in the polycrystalline silicon epitaxial layer is substantially lower as compared to the density of intragrain defects in epitaxial layers grown on prior art metal-induced-crystallization based seed layers. Polycrystalline silicon layers epitaxially grown on the seed layers fabricated according to the method may for example be used as an active layer in photovoltaic cells. It is an advantage of the lower density of intragrain defects that better photovoltaic cell performances can be obtained.

In a first aspect of the present invention a method for forming a crystalline silicon layer on a substrate is provided, the method comprising the steps of: performing a metal induced crystallization process, the process comprising: depositing a metal, e.g. aluminum, on the substrate at a first temperature, the metal having an external surface; oxidizing the external surface of the metal at a second temperature; depositing amorphous silicon on the oxidized external surface of the metal at a third temperature; annealing the metal and the silicon at a fourth temperature, whereby a crystalline silicon layer is obtained on the substrate covered by an external layer comprising the metal, and removing the external layer comprising the metal thereby exposing the crystalline silicon layer, wherein at least the first temperature and the fourth temperature (crystallization temperature) are not lower than about 200° C.

A second aspect of the present invention provides a crystalline silicon layer obtained by the above-mentioned method.

A third aspect of the present invention provides a process for epitaxially growing a polycrystalline silicon layer on the above-mentioned crystalline silicon layer, which has been optionally processed.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 shows 80×80 μm² sized top view IPF-EBSD maps of AIC seed layers crystallized at temperatures of 420° C. (FIG. 1(a)) and 550° C. (FIG. 1(b)).

FIG. 2 illustrates the texture of AIC seed layers crystallized at different temperatures (420° C., 460° C., 500° C. and 550° C.) based on EBSD measurements, expressed in percentage of the total indexed points within 15° and 20° off the <001>, <011> and <111> directions.

FIG. 3 is a top view SEM image of defect etched polycrystalline silicon layers made by epitaxial thickening of AIC seed layers. The seed layers were crystallized at a temperature of 420° C. (FIG. 3(a)) and 550° C. (FIG. 3(b)).

FIG. 4 shows SEM, EBSD and EBIC measurements on the same area of a polycrystalline silicon layer after polishing of the surface and emitter formation by diffusion of phosphorous. FIG. 4(a) shows a top view SEM, FIG. 4(b) shows a top view IPF EBSD map, FIG. 4(c) shows a CSL map (less dark lines indicating Σ3 boundaries) projected on top of the EBSD band contrast and FIG. 4(d) shows an EBIC measurement.

FIG. 5 shows quantitative SIMS profiles of C and O measured with negative ion detection (with a higher O signal than C signal) and B, Cu, Al measured with positive ion detection.

FIG. 6 shows photoluminescence measurement results at liquid helium temperature of polycrystalline silicon layers made by epitaxial thickening of an AIC seed layer crystallized at temperatures of 420° C., 460° C., 500° C. and 550° C. FIG. 6(a) shows measurements without passivation with the peak at ca. 0.82 eV increasing with decreasing crystallization temperature and the peaks in range of 0.97 to 1.00 eV increasing with increasing crystallization temperature; FIG. 6(b) shows results after hydrogen plasma passivation of the same samples with the peak at ca. 0.82 eV increasing with decreasing crystallization temperature and the peaks in range of 0.97 to 1.00 eV increasing with increasing crystallization temperature.

FIG. 7 is a cross section TEM image of an AIC seed layer annealed at a temperature of 500° C.

FIG. 8 is a cross section TEM image of an AIC seed layer annealed at a temperature of 420° C.

FIG. 9 shows cross section TEM images of an epitaxially thickened AIC seed layer, for a seed layer crystallized at a temperature of 500° C.

FIG. 10 shows a cross section TEM image of an epitaxially thickened AIC seed layer, for a seed layer crystallized at a temperature of 420° C.

FIG. 11 shows cross section TEM images of AIC seed layers made on glass ceramic (FIG. 11(a)) and on oxidized silicon wafer (FIG. 11(b)).

FIG. 12 shows a flowchart of one embodiment of a method of forming a crystalline silicon layer on a substrate.

In the different figures, the same reference signs refer to the same or analogous elements.

### DETAILED DESCRIPTION OF CERTAIN ILLUSTRATIVE EMBODIMENTS

The present invention will be described with respect to particular embodiments and with reference to certain drawings but the invention is not limited thereto, but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

The following terms are provided solely to aid in the understanding of the invention.

### DEFINITIONS

The term macroroughness, as used herein, means RMS roughness, which is defined as the standard deviation or the square root of the variance of the height distribution of points within the image. The degree of macroroughness can be quantified by the maximum deviation from an average level line 11, as illustrated in FIG. 15. An average level line 11 is a reference line from which profile deviations are measured. As an average level line 11, one can use the least squares mean line, which is a line through a profile 12 such that the sum of the squares of the deviations 10 of the profile from the average level line 11 is minimized. A measure for the macroroughness can be the maximum deviation from this average level line 11.

The term microroughness is defined by the ASTM F-1 Electronic Committee as surface roughness components with spacings between irregularities (spatial wavelength) less than about 100 μm. The degree of microroughness can be quantified by the parameter μRN, defined as the relative mean distance and variance between two side by side microrough defects along a characteristic profile line of the surface. A surface can be macrorough but not microrough. Alternatively, a surface can be macroflat and at the same time microrough.

The term “microflattening”, as used herein, means process in which a dielectric layer is applied to the substrate, which reduces the roughness of the surface thereof. The dielectric may comprise a spin-on dielectric, e.g. spin-on oxide, a flowable dielectric, e.g. flowable oxide (which can sometimes also be a spin-on oxide), a dip-on dielectric, e.g. dip-on oxide, or a spray-on dielectric, e.g. spray-on oxide. In some embodiments, the dielectric may comprise a spin-on glass or SiO₂.

Metal-induced crystallization, MIC, as used herein, means a method by which amorphous silicon, a-Si, can be turned into polycrystalline silicon at relatively low temperatures. In MIC a metal layer, such as aluminum, deposited onto a substrate, usually glass or Si, and then capped with an amorphous silicon film. The structure is then annealed at temperatures below the metal/silicon eutectic temperature, which in the case of aluminum is at about 577° C. so that annealing is performed in the temperature range between about 200° C. and 550° C. which causes the a-Si films to be transformed into polycrystalline silicon.

Aluminum-induced crystallization, AIC, as used herein, means a process in which first an aluminum layer is deposited on a foreign substrate. Next the aluminum layer is oxidized (for instance by exposure to air) to form a thin layer of aluminum oxide. Then, amorphous silicon is deposited on the aluminum oxide layer. The sample is then annealed at a temperature (AIC crystallization temperature) below the silicon/aluminum eutectic point. During annealing, a layer exchange takes place: the silicon atoms diffuse into the aluminum layer and crystallize together. The aluminum atoms move to the top surface. After this layer exchange, the final structure comprises a layer of large grain polycrystalline silicon (e.g. typically with grain sizes in the range from 1 μm to 100 μm) on the foreign substrate, covered by an aluminum layer with Si enclosures. The layer exchange thus involves a conversion of the amorphous silicon layer into a polycrystalline silicon layer. Typically the aluminum layer is then etched away. The resulting silicon layer may contain some secondary crystallites, formed in the top aluminum layer during crystallization. Secondary crystallites with vertical side walls and a smooth upper surface are often referred to as ‘islands’.

The term “crystalline silicon layer”, as used herein, means the silicon layer resulting from a metal-induced crystallization process.

The term “seed layer”, as used herein, means the silicon layer optionally processed crystalline silicon layer on which a polycrystalline layer is epitaxially grown, which if no further treatment is performed will be the “crystalline silicon layer”, but will usually be the crystalline silicon layer after having been subjected to further treatment e.g. to remove secondary silicon crystallites formed in the metal layer during crystallization.

The invention will now be described by a detailed description of several embodiments of the invention. It is clear that other embodiments of the invention can be configured according to the knowledge of persons skilled in the art without departing from the true spirit or technical teaching of the invention, the invention being limited only by the terms of the appended claims.

It is to be understood that although preferred embodiments, specific constructions and configurations, as well as materials, have been discussed herein for devices according to the present invention, various changes or modifications in form and detail may be made without departing from the scope and spirit of this invention. For example, any formulas given above are merely representative of procedures that may be used. Functionality may be added or deleted from the block diagrams and operations may be interchanged among functional blocks. Steps may be added or deleted to methods described within the scope of the present invention.

### Process According to the First Aspect of the Present Invention

According to one embodiment of the first aspect of the present invention, the metal layer is an aluminum layer. The first temperature, the second temperature, the third temperature and the fourth temperature are preferably lower than the aluminum/silicon eutectic point. For example, the first temperature and the fourth temperature (crystallization temperature) can be in the temperature range between about 200° C. and 550° C., particularly in the temperature range between about 300° C. and 550° C., and particularly in the temperature range between about 420° C. and 550° C. The second temperature and the third temperature can be in the range between about 18° C. and 550° C., particularly in the temperature range between about 200° C. and 550° C., particularly in the temperature range between about 300° C. and 550° C., and particularly in the temperature range between about 420° C. and 550° C.

According to one embodiment of the first aspect of the present invention, the first, third and fourth temperatures are substantially identical, e.g., are within about 50° C. of one another, with in about 20° C. of one another. In one embodiment, they are identical.

According to one embodiment of the first aspect of the present invention the first temperature, the second temperature, the third temperature and the fourth temperature are substantially identical, e.g., are within about 50° C. of one another, with in about 20° C. of one another. In one embodiment, they are identical.

According to one embodiment of the first aspect according to the present invention, at least two of the first temperature, the second temperature, the third temperature and the fourth temperature are substantially different from one another, e.g., greater than about 50° C. different from one another.

According to one embodiment of the first aspect of the present invention, if the metal layer, e.g., aluminum layer, and the amorphous silicon layer are deposited at a temperature not lower than about 200° C., e.g., at the crystallization temperature, a heating step and thus a change in temperature after deposition of these layers can be avoided or the degree of heating substantially reduced, e.g., kept to below about 100° C. and particularly below about 50° C. The formation of defects (in the seed layer), e.g. intra-grain defects, resulting from a difference in the coefficient of thermal expansion (CTE) between e.g. the substrate and the metal layer is thereby avoided or substantially reduced e.g. reduced by at least a factor of 2.

According to one embodiment of the first aspect of the present invention, if the third temperature is in the range between about 200° C. and 550° C., the deposition of the amorphous silicon layer is directly followed by the annealing step for realizing aluminum induced crystallization with the duration of the annealing step at the fourth temperature being preferably sufficiently long for the amorphous silicon layer to be converted into a polycrystalline silicon layer (seed layer) on the substrate.

According to one embodiment of the first aspect of the present invention, if the metal layer, e.g. aluminum layer, is deposited at a temperature higher than about 200° C., e.g., at the crystallization temperature, and the amorphous silicon layer is deposited at a lower temperature, followed by heating the structure up to the crystallization temperature, it is preferred that stress in the metal layer, e.g. aluminum layer, resulting from a difference in CTE between the substrate and the metal layer be avoided or substantially reduced at the moment of crystallization and formation of a seed layer.

According to one embodiment of the first aspect of the present invention, the removal of the external layer comprising the metal substrate comprises removing silicon islands in the external layer, thereby using the metal layer as a mask; and removing the metal layer.

In one embodiment, the method comprises forming on a foreign substrate an aluminum layer, wherein deposition of this aluminum layer is performed at an elevated temperature, e.g., at a temperature not lower than about 200° C. The aluminum layer is deposited at a temperature below the aluminum/silicon eutectic point, e.g., at a temperature in the range between about 200° C. and 550° C., e.g. in the range between about 300° C. and 550° C., e.g. in the range between about 420° C. and 550° C. For example, the aluminum layer can be deposited at a temperature substantially equal to the AIC crystallization temperature. However, the method is not limited thereto and the aluminum layer can also be deposited at a temperature higher than the AIC crystallization temperature or at a temperature lower than the AIC crystallization temperature.

Next the aluminum layer is oxidized, for example at the temperature of deposition of the aluminum layer, thereby forming a thin layer of aluminum oxide. However, the method is not limited thereto and the aluminum oxidation can also be performed at a temperature higher than the aluminum deposition temperature or at a temperature lower than the aluminum deposition temperature. Subsequently an amorphous silicon layer is deposited on the aluminum oxide layer. In one embodiment the amorphous silicon layer is deposited at a temperature below the aluminum/silicon eutectic point, e.g., at a temperature in the range between about 18° C. and 550° C., e.g. at a temperature in the range between about 200° C. and 550° C., e.g., at a temperature in the range between about 300° C. and 550° C., e.g., in the range between about 420° C. and 550° C. For example, the amorphous silicon layer can be deposited at a temperature substantially equal to the AIC crystallization temperature. For example, the amorphous silicon layer can be deposited at the same temperature as the aluminum layer. However, the method is not limited thereto and the amorphous silicon layer can also be deposited at a temperature higher than the crystallization temperature or at a temperature lower than the crystallization temperature and/or at a temperature different from the temperature of deposition of the aluminum layer.

In embodiments wherein the amorphous silicon layer is deposited at an elevated temperature, e.g. at a temperature not lower than about 200° C., a crystallization process can start during deposition of the amorphous silicon layer, especially if the deposition of this layer is done at the AIC crystallization temperature, involving a layer exchange between the amorphous silicon layer and the aluminum layer. It is known that a change in temperature of the structure before the AIC process is finished can result in an increased nucleation density. Therefore, in such embodiments, preferably the deposition of the amorphous silicon layer is directly followed by the crystallization process itself. The substrate with the aluminum layer and the silicon layer is therefore preferably maintained at the AIC crystallization temperature, till a polycrystalline silicon layer is formed on the substrate with an aluminum layer on top of it. The aluminum layer can be removed afterwards.

In one embodiment, stress (resulting from a difference in CTE combined with a change in temperature) in the aluminum layer during the crystallization step can be avoided or substantially reduced, by performing at least the deposition of the aluminum layer at an elevated temperature, e.g. at the crystallization temperature. This is in contrast to prior art MIC or AIC processes, wherein the deposition of the metal (e.g. aluminum) and amorphous silicon is performed at temperatures close to room temperature, e.g. at a temperature in the range between about 10° C. and 30° C., e.g. at a temperature in the range between about 18° C. and 22° C. In order to initiate the crystallization process in prior art methods, the substrate with the aluminum layer and the amorphous silicon layer is heated to the crystallization temperature, which may be typically, e.g., about 200° C. to 550° C. higher than the deposition temperature. If the CTE of the substrate is different from the CTE of the aluminum layer, heating up to the crystallization temperature leads to a stressed aluminum layer. This means that the growing silicon grains are formed in a stressed layer. This stress may be an important origin for intra-grain defects in the resulting seed layer. In one embodiment, this stress in the aluminum layer is avoided or substantially reduced, and thus the density of intra-grain defects in the resulting seed layer can be substantially reduced as compared to prior art AIC based methods.

In prior art AIC processes, the substrates were selected from the viewpoint of epitaxial growth, with a CTE as close as possible to the CTE of silicon. However, if stress in the aluminum layer is indeed one of the origins of intra-grain defects, it may be better to use substrates with a CTE close to the one of aluminum. However, as the CTE of silicon is about seven times smaller than the CTE of aluminum, this approach may only be applicable in combination with low temperature epitaxial growth.

Certain embodiments provide another possible solution, wherein the substrate has a CTE close to that of silicon (as in prior art), making the process compatible with high temperature epitaxial growth. In certain embodiments of the present invention both the aluminum and the silicon layer are deposited at the AIC crystallization temperature. In this case the stress is only determined by the deposition method and deposition conditions and not additionally by the heating. In certain embodiments of the present invention it is preferred that the deposition is directly followed by the AIC crystallization step, because nucleation will already start during deposition of the amorphous silicon layer.

In one embodiment, the method comprises forming on a foreign substrate an aluminum layer, wherein deposition of this aluminum layer is performed at an elevated temperature, e.g. at a temperature not lower than about 200° C. The aluminum layer is preferably deposited at a temperature below the aluminum/silicon eutectic point, e.g. at a temperature in the range between about 200° C. and 550° C., e.g. in the range between about 300° C. and 550° C., e.g. in the range between about 420° C. and 550° C. For example, the aluminum layer can be deposited at a temperature substantially equal to the AIC crystallization temperature. However, the method is not limited thereto and the aluminum layer can also be deposited at a temperature higher than the AIC crystallization temperature or at a temperature lower than the AIC crystallization temperature. Next the aluminum layer is oxidized, for example at the temperature of deposition of the aluminum layer, thereby forming a thin layer of aluminum oxide. However, the method is not limited thereto and the aluminum oxidation can also be performed at a temperature higher than the aluminum deposition temperature or at a temperature lower than the aluminum deposition temperature. Subsequently an amorphous silicon layer is deposited on the aluminum oxide layer. Preferably the amorphous silicon layer is deposited at a temperature below the aluminum/silicon eutectic point, e.g. at a temperature in the range between about 18° C. and 550° C., e.g. at a temperature n the range between about 200° C. and 550° C., e.g. at a temperature in the range between about 300° C. and 550° C., e.g. in the range between about 420° C. and 550° C. For example, the amorphous silicon layer can be deposited at a temperature substantially equal to the AIC crystallization temperature. For example, the amorphous silicon layer can be deposited at the same temperature as the aluminum layer. However, the method is not limited thereto and the amorphous silicon layer can also be deposited at a temperature higher than the crystallization temperature or at a temperature lower than the crystallization temperature and/or at a temperature different from the temperature of deposition of the aluminum layer. In embodiments wherein the amorphous silicon layer is deposited at an elevated temperature, e.g. at a temperature not lower than about 200° C., a crystallization process can start during deposition of the amorphous silicon layer, especially if the deposition of this layer is done at the AIC crystallization temperature, involving a layer exchange between the amorphous silicon layer and the aluminum layer. It is known that a change in temperature of the structure before the AIC process is finished can result in an increased nucleation density. Therefore, in such embodiments, preferably the deposition of the amorphous silicon layer is directly followed by the crystallization process itself. The substrate with the aluminum layer and the silicon layer is therefore preferably maintained at the AIC crystallization temperature, till a polycrystalline silicon layer is formed on the substrate with an aluminum layer on top of it. The aluminum layer can be removed afterwards.

According to one embodiment of the first aspect of the present invention, the substrate comprises at least one material selected from the group consisting of or comprising a ceramic material, glass, a glass-ceramic material, mullite, alumina, and silicon nitride.

According to one embodiment of the first aspect of the present invention, the substrate has a microroughness higher than about 2 rad/μm.

According to one embodiment of the first aspect of the present invention, the substrate has a microrough face and the microroughness is reduced thereby providing a microflattened face and the metal is deposited on the microflattened face of the substrate.

According to one embodiment of the first aspect of the present invention, the crystalline silicon layer is subjected to hydrogen plasma passivation. This treatment has the effect of rendering electrically active silicon defects in the crystalline silicon layer non-electrically active.

According to one embodiment of the first aspect of the present invention, the crystalline silicon layer is subjected to laser annealing. This treatment has the effect of rendering electrically active silicon defects in the crystalline silicon layer non-electrically active.

According to one embodiment of the first aspect of the present invention, the method further comprises the step of epitaxially growing a polycrystalline silicon layer on the crystalline silicon layer.

### INDUSTRIAL APPLICABILITY

A polycrystalline silicon layer grown epitaxially on a seed layer formed according to a method described above can advantageously be used as an active layer for a device such as a photovoltaic cell. However, the method, according to one embodiment, can be used for providing polycrystalline silicon layers for other devices, such as for example thin film transistors and flat panel displays.

### EXAMPLES

### Experiments Performed to Investigate Origin and Formation of Intra-Grain Defects in Polycrystalline Silicon Layers Made by Epitaxial Thickening of AIC Seed Layers

Three different substrates were used for the experiments: alumina ceramic (CoorsTek ADS996), glass-ceramic (Corning Inc code 9664) and wet oxidized silicon wafers with an oxide thickness of 400 nm. The root mean square (RMS) surface roughness of the alumina, glass-ceramic and oxidized silicon wafers substrates was about 130 nm, about 2 nm and less than 1 nm respectively. All substrates were chemically cleaned before use and the alumina substrates were smoothed with a spin-on oxide (single FOx-25 layer giving a final RMS surface roughness of about 45 nm).

To form the AIC seed layer, a stack of Al and a-Si layers was deposited in an electron-beam high vacuum evaporator with the substrate being neither heated nor cooled i.e. nominally at room temperature. However, whereas during aluminum deposition the substrate temperature did not rise above 40° C., during amorphous silicon deposition the substrate temperature rose to between 50° C. and 60° C. In between the two depositions, the aluminum layer was oxidized by exposure to air for two minutes. The nominal thickness of the Al and a-Si layers was 200 nm and 230 nm respectively. After deposition, the samples were annealed in a tube furnace under nitrogen ambient at 420-550° C. for a time (depending on the annealing temperature) between 4 and 60 hours. During this annealing the a-Si crystallized into (poly)crystalline silicon and the layers exchanged places resulting in a (poly)crystalline silicon seed layer with secondary silicon crystallites (sometimes also referred to as islands) embedded in an Al layer on top of the seed layer. On some seed layers the secondary silicon crystallites were removed by selective reactive ion etching. The residual Al was removed by wet chemical etching [H₃PO₄/H₂O/CH₃COOH/HNO₃ solution with a 16:2:1:1 ratio].

The as-formed seed layers received a full RCA clean before epitaxial growth. The epitaxial growth of a polycrystalline silicon layer on top of the seed layers was performed in a single-wafer chemical vapor deposition (CVD) reactor (ASM Epsilon2000) under atmospheric pressure, at a temperature of 1130° C. The growth rate was about 1.4 μm min⁻¹. Double layers of p+ and p-type silicon with nominal thicknesses of 0.5 and 3 μm respectively were realized. Typical doping densities were 2×10¹⁹ cm⁻³ for the p+ layer and 3×10¹⁶ cm⁻³ for the p-layer. The formation and-electrical behavior of the intra-grain defects in such epitaxial layers was investigated.

After epitaxial growth the 10×10 cm² samples were cut into pieces for use either for characterization or for photovoltaic cell fabrication. The pieces used for photovoltaic cell fabrication were plasma hydrogenated in a plasma-enhanced chemical vapor deposition (PECVD) system at 400° C. before emitter formation. An n-type emitter was created by deposition of thin double layers of undoped and P-doped a-Si using PECVD at a sample temperature of 165° C. The total thickness of this heterojunction emitter was about 15 nm. To complete the cells, a conductive indium tin oxide layer was deposited by RF-sputtering. This layer was used as an anti-reflective coating and it lowers the series resistance. The contacts were formed by photolithography and wet chemical etching in combination with metal evaporation. Both emitter and base contacts were on top of the cell (interdigitated contacts). All cells were measured under Air Mass 1.5 (1000 W m⁻²) illumination with an aperture area of 1 cm².

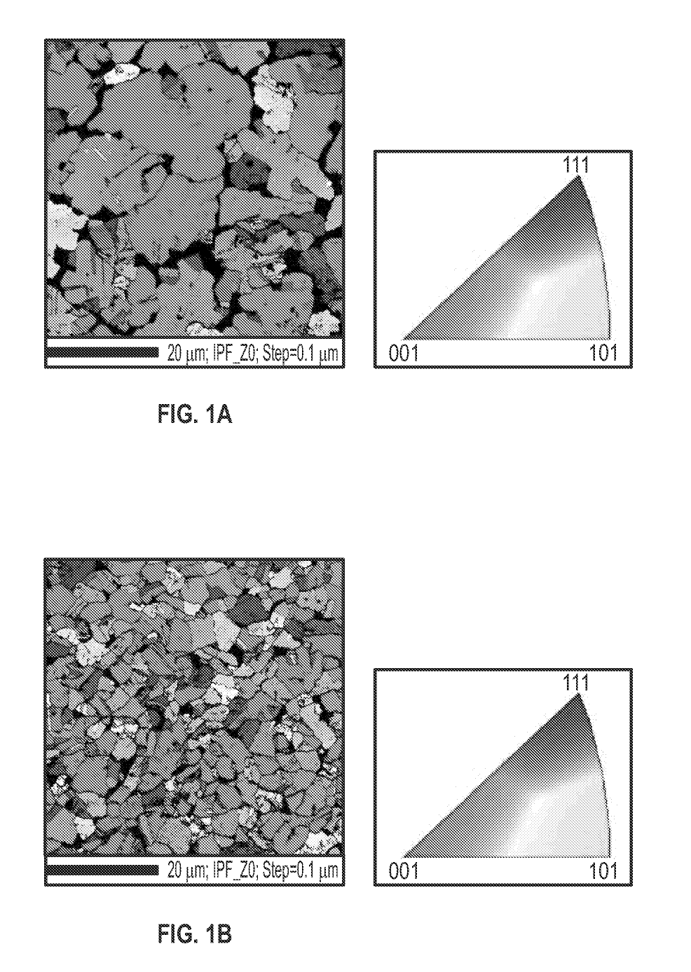

In a good, i.e. efficient, polycrystalline silicon layer the grain boundaries are the only crystallographic (and potentially electrical) defects present. An improved material quality, and thus an improved device performance, is then to be expected with increasing grain size of the polycrystalline silicon layer. It is known that for the AIC process the final grain size increases as the crystallization temperature is decreased. The effect of grain size enlargement on the solar cell performance was investigated by using crystallization temperatures for the AIC process between 420° C. and 550° C. Automated EBSD measurements were performed in a FEI quanta 200 FEG-SEM equipped with a Oxford instruments NordlysII detector to map the crystal orientation over relatively large areas, typically 80×80 μm² with a step size of 0.1 μm. From these measurements, information was obtained about orientation and grain size distribution as well as the presence and position of coincident side lattice (CSL) boundaries. FIGS. 1(a) and 1(b) show two top view inverse pole figure (IPF) EBSD maps of AIC layers processed together, except for the annealing or crystallization step that was done at 420° C. (FIG. 1(a)) and 550° C. (FIG. 1(b)) respectively. In these 80×80 μm² maps each color represents a crystallographic orientation orthogonal to the sample surface.

To improve the indexing, secondary crystallites were removed prior to the EBSD measurements. The grain size was observed to be inversely proportional to the crystallization temperature. By lowering the crystallization temperature from 550° C. to 420° C. the maximum grain size increased by-a factor of about 5 (ca. 10 μm compared to ca. 50 μm). Mainly Σ3 coincidence site lattice (CSL) boundaries were present, as evidenced by CSL maps made from the same set of data points. Besides individual Σ3 boundaries resulting in large twinned regions, narrow micro-twinned regions defined by parallel Σ3 boundaries close together were also found. Such narrow bands were also visible in the inverse pole figure maps (FIG. 1(a) and FIG. 1(b)).

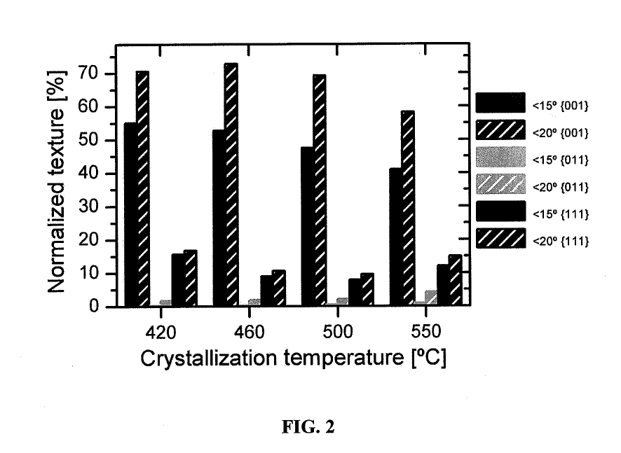

FIG. 2 shows the fraction in percentage of the total indexed points within 15° and 20° off the <001>, <011> and <111> directions for crystallization temperatures of 420° C., 460° C., 500° C. and 550° C. The size of the maps on which FIG. 2 is based was 600×600 μm² with a step size of 1 μm for crystallization temperatures of 420° C. and 460° C. and 80×80 μm² with a step size of 0.1 μm for the other two temperatures. All crystallization temperatures result in a clear preferential (001) orientation, although some decrease in preferential orientation was found with increasing crystallization temperature. Especially for low temperature epitaxial growth of silicon, a preferential (001) orientation of the seed layer is preferred since epitaxial growth at low temperatures leads to much fewer defects on (001) oriented silicon compared to other orientations.

Photovoltaic cells with the same epitaxial layer thickness and doping level and identical processing, but based on seed layers crystallized at different temperatures, were made to verify the influence of the grain size on the global electrical quality of the epitaxial layers. From each layer, twelve 1 cm² sized photovoltaic cells were formed. All photovoltaic cells were passivated by plasma hydrogenation. Table 1 summarizes the main photovoltaic cell parameters averaged over the five cells with the highest V_{oc}. The V_{oc} is almost independent of both the grain size and the slight difference in preferential (001) orientation.

TABLE 1

| Annealing | Maximum grain | V_{oc} | J_{sc} | FF | Eff |
|---|---|---|---|---|---|
| temperature [° C.] | size [μm] | [mV] | [mA/cm²] | [%] | [%] |
| 420 | 50 | 473.6 | 16.6 | 69.0 | 5.4 |
| 460 | 30 | 480.7 | 17.3 | 69.8 | 5.8 |
| 500 | 17 | 474.0 | 17.5 | 70.3 | 5.8 |
| 550 | 10 | 474.8 | 17.2 | 70.3 | 5.8 |

This indicates that the expected improvement of the electrical quality of the epitaxial layer with larger grain size is not present. Besides the V_{oc} the short circuit current density (J_{sc}), the fill factor (FF) and the efficiency (eff) also do not change significantly with changing grain size.

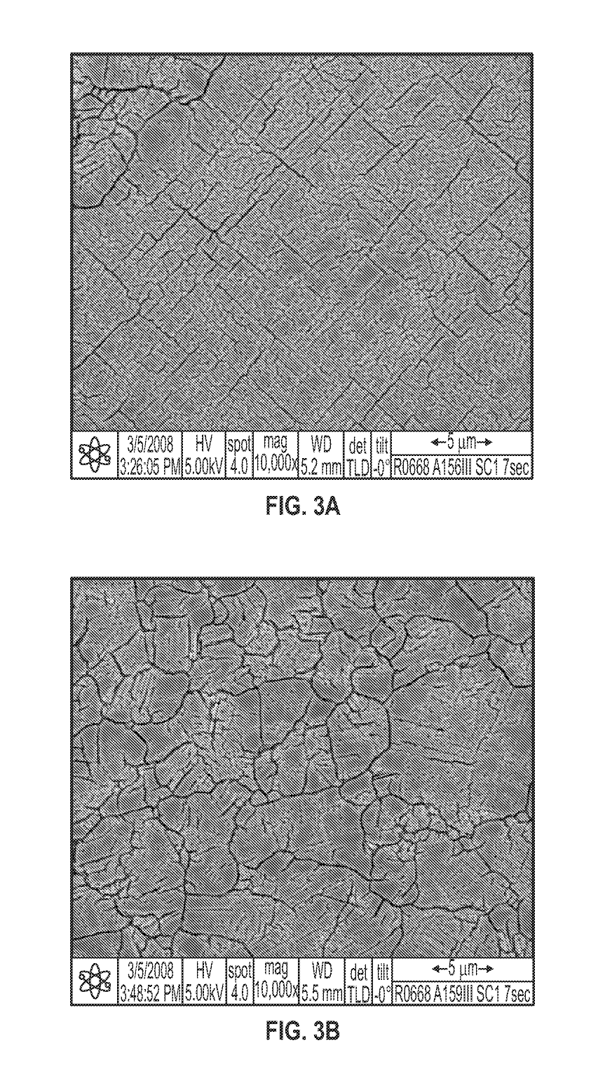

The grain size and crystallographic defects present in the epitaxial layers used for the different photovoltaic cells were further investigated by combining defect etching with SEM imaging. The epitaxial layers were polished and subsequently etched with a slightly adapted Schimmel defect etch. Images of the defect etched layers were taken with a NOVA200 SEM. FIGS. 3(a) and 3(b) show two SEM images at the same scale of defect etched layers that are grown on seed layers crystallized at 420° C. and 550° C. respectively. The grain sizes of both layers are clearly different (the maximum grain size for each layer is indicated in Table 1) but the intra-grain defect densities are quite similar. The defect etched marks consist mostly of points or lines. These were attributed to dislocations and stacking faults, but twins can also give rise to defect etched lines. Besides grains with the typical defect etched pattern shown in FIG. 3(a), grains/regions with deeper and irregular etched patterns were also found in all the investigated layers. EBSD investigations seem to indicate that these grains/regions have orientations normal to the surface that are at least more than 15° off the <001> direction.

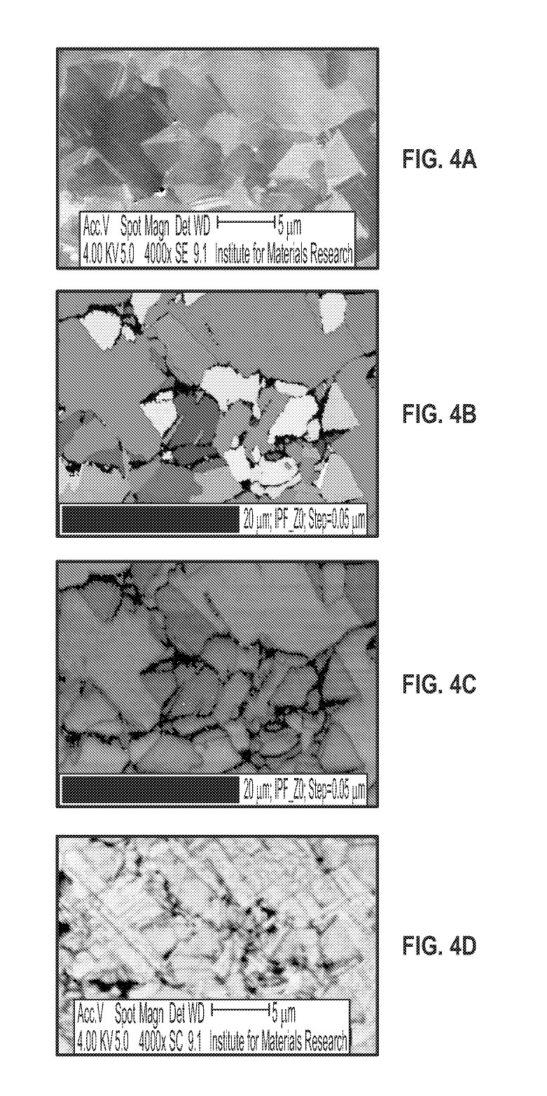

The electrical activity of the observed intra-grain defects in the polycrystalline silicon layers was verified by performing room temperature EBIC measurements, which show the position-dependent short circuit current. These EBIC measurements were performed in a Philips XL 30 system. The junction needed for these measurements was created by diffusion of phosphorus atoms from a POCl₃ ambient at a temperature of 845° C. The polycrystalline silicon layer was polished after epitaxial growth and before emitter formation. The RMS roughness of the surface after polishing was only a few nanometers. The influence of the surface roughness on the EBIC signal was therefore negligible. Moreover, channel contrast in scanning electron (SE) images was improved compared to non-polished samples. This allowed an estimation to be made of the grain and twin boundaries present in the investigated area, as can be seen in FIG. 4(a). Both types of boundary are observable as separation lines between two regions with different channeling contrast. A slight change in orientation inside a grain is seen as a gradual contrast change.

FIG. 4(b) shows a high resolution (step size of 50 nm) IPF-EBSD map of the same area after extrapolation used to improve the CSL indexing shown in FIG. 4(c). In this figure, Σ3 boundaries are the less dark lines and shown on top of the band contrast image of the EBSD measurement. A pattern similar to the one obtained with SEM was found, although not all contrast changes were found back in the IPF-EBSD map. In particular most of the narrow bands, which are correlated to Σ3 boundaries, have disappeared, indicating that Σ3 boundary detection by EBSD is not straightforward. Due to the relatively large step size, a region with an even number of multiple twin planes close together, resulting in the same orientation at both sides of the twinned region, will not be revealed by EBSD. Hence only relatively wide twinned regions will be observed by EBSD. The EBSD measurement in FIG. 4(c) confirmed the presence of Σ3 boundaries, some narrow bands and general grain boundaries in the area of the EBIC measurements (FIG. 4(d)).

No defect passivation step was applied to the sample shown in FIG. 4. By comparing the SEM, EBSD and EBIC images it can be concluded that the general grain boundaries as well as the Σ3 boundaries and narrow bands act as recombination centers, since they appear darker in the EBIC images. The Σ3 boundaries were found to be contaminated.

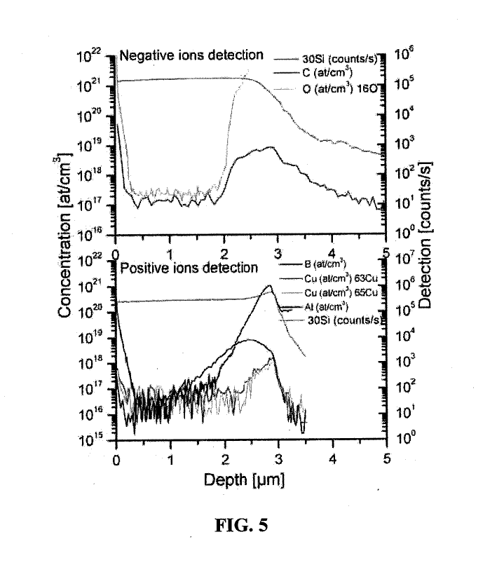

The presence of Cu, Al, C and O contaminants was investigated by quantitative SIMS analyses (see FIG. 5) on a sample similar to the one shown in FIG. 4. Cs⁺ primary ion- and negative ion-detection was used for detection of C and O. In order to decrease the detection limit, fast sputtering rates after a long pumping down of the analytical chamber were used. O²⁺ primary ion- and positive ion-detection was used for B, Cu and Al detection. Both copper ⁶³Cu and ⁶⁵Cu isotope signals were used, taking into account the natural relative isotopic abundance. If both signals gave equal results mass interference seemed very unlikely. Due to the relatively high roughness of the polycrystalline silicon surface after epitaxial growth the depth resolution was quite poor.

The depth calibration was deduced from the sputtering rate obtained from crater depth measurement with a stylus profiler in silicon. Quantitative measurements were possible due to measurements on implanted silicon standards analyzed in the same run. A Cu concentration with an upper limit of around 1×10¹⁷ cm⁻³ was present in the top part of the epitaxial layer. The increased Cu concentration towards the AIC seed layer suggests the AIC seed layer as the source of Cu contamination, not the FOx layer because SIMS measurements on similar samples made on bare alumina substrates and oxidized silicon wafers also showed similar Cu profiles. As to be expected a high concentration of Al was found in the region of the seed layer, decreasing to a value similar to the Cu concentration in the epitaxially grown layer.

The use of aluminum and e-beam evaporation during seed layer formation results in a process prone to metal contamination. However, harmful metal contamination may not be an intrinsic problem of the AIC seed layer process. A C-signal was also found through the whole of the investigated polycrystalline silicon layer. The O-concentration signal was equal to the residual signal coming from in-situ surface contamination. The O-concentration in the material was therefore less than or equal to 2−3×10¹⁷ cm⁻³. The presence of these contaminants can possibly explain the electrical activity of the Σ3 boundaries.

Besides general grain boundaries, Σ3 boundaries and the narrow twin bands, other electrically active defects that could not be observed by channel contrast were also found inside the grains. By comparing the intra-grain defect pattern found by EBIC in a region with uniform channel contrast with the one found by defect etching it can be concluded that these defects are dislocations in the case of dots and stacking faults or micro-twinned regions in the case of lines.

Combining defect etching, photovoltaic cell results and EBIC measurements it can be concluded that the intra-grain defects are a major limitation for the device performance. Therefore, in order to further improve photovoltaic cell performance, there is a need to reduce the intra-grain defect density, avoid contaminants and/or passivate defects.

### Experiments Performed to Investigate the Effect of Hydrogen Plasma Passivation on Grain Boundaries and Intra-Grain Defects.

It has been established that hydrogen plasma passivation of polycrystalline silicon photovoltaic cells can result in a substantial increase of V_{oc}. Which defects and to what extent they are passivated is still not completely clear. Therefore, EBIC measurements were also performed on passivated photovoltaic cells. Hydrogen plasma passivation was performed after emitter formation. After passivation similar defect patterns of lines and points were found as in FIG. 4(d), showing that the hydrogen plasma passivation is not completely passivating the intra-grain defects and the grain boundaries. From the EBIC measurements it was not possible to obtain a reliable estimate for the absolute electrical activity reduction of the extended defects by hydrogen plasma passivation.

To further investigate the intra-grain defects and the influence of hydrogen plasma passivation on the polycrystalline silicon layers, photoluminescence (PL) measurements at liquid helium temperature were performed. The excitation laser used for the measurements had a wavelength of 532 nm and a power of 0.2 W. Optical spectra were measured using a Roper Scientific SpectraPro 300i spectrograph with a Princeton Instruments ST-133 controller and an OMA-V:512-1.7 InGaAs 1D CCD detector head cooled by liquid nitrogen. The total luminescence spectra from 1100 nm up to 1650 nm were determined by 3 overlapping measurements. In monocrystalline silicon, luminescence of dislocations, whether or not related to the presence of impurities, is already well studied. The typical dislocation luminescence peaks, the so called D1 to D4 peaks, are observed at energies of 0.812, 0.875, 0.934 and 1.000 eV respectively. Whereas sharp dislocation-related peaks have been reported for monocrystalline silicon, a broad peak was reported for fine-grained polycrystalline silicon with a grain size of the order of 100-300 nm. However a change from sharp peaks to a broader band can also be attributed to a change in dislocation density.

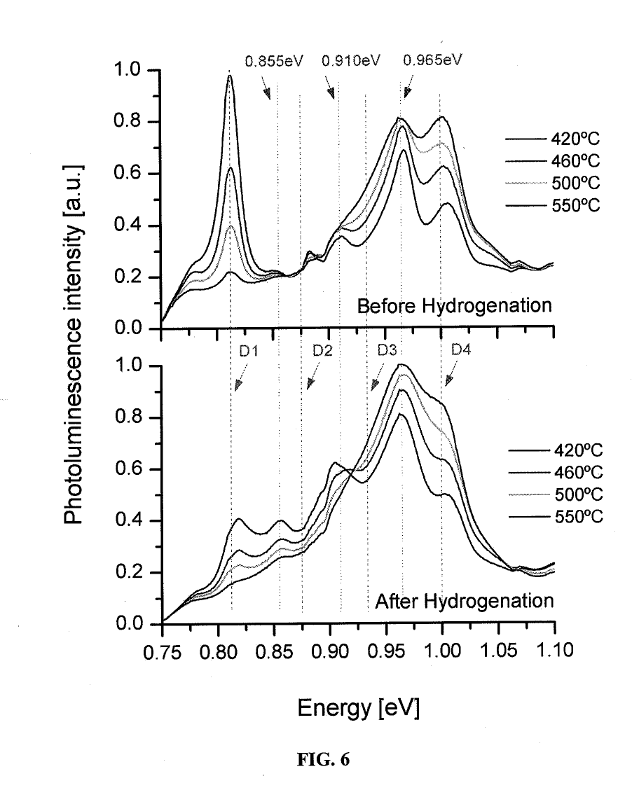

FIG. 6 shows the PL spectra for four epitaxially thickened AIC seed layers with and without hydrogen plasma passivation. The four seed layers were crystallized at different temperatures (420° C., 460° C., 500° C. and 550° C.) and the epitaxial layers therefore had different grain sizes. For each temperature the same samples were used for both measurements with and without passivation. To eliminate as much as possible the influence of different reflection properties of the samples, the four curves of each graphs were normalized to the same total intensity for energies between 0.75 eV and 1.10 eV. The same peaks were found for all four samples, although their relative intensity changed with crystallization temperature and hydrogen plasma passivation. The D1 and D4 peaks were found in all the samples, whereas the D2 and D3 peaks were not observed. Peaks with energies of 0.965 eV, 0.910 eV and 0.855 eV were found instead. Before hydrogenation, a relative increase upon decreasing the crystallization temperature (and therefore increasing grain size). The D1 peak can be associated with the presence of oxygen in grain boundary-free samples. Photoluminescence with an energy of 1.014 eV can be associated with copper centers in crystalline silicon. If D band luminescence is related to the presence of impurities at dislocations, the PL spectra suggest a different impurity concentration at the dislocations. Supposing that the contamination was coming from the AIC seed layer deposition (as supported by SIMS and Total Reflection X-Ray Fluorescence (TXRF) measurements) and since all samples are processed together, the same concentration of impurities can be expected for all the samples. A possible explanation for the relative change of luminescence with grain size could therefore be a different concentration of dislocations in the different samples (due to the varying grain size and the possibility of dislocations present at grain boundaries and/or a different intra-grain dislocation density) or segregation of impurities to the grain boundaries or defects. It is not yet clear if the grain boundaries are only influencing the spectra by the possible presence of dislocations or also in other ways.

Hydrogen passivation has a clear influence on the measured PL spectra. After hydrogenation, the D1 and D4 peaks are clearly suppressed with respect to the 0.965 eV luminescence peak. The difference in shape of the luminescence spectra between all samples is much smaller than before passivation: the ratio between the 0.965 eV luminescence peak and the two D1 and D2 peaks of the different samples becomes more equal. Since all four samples have different grain sizes, this could suggest that hydrogen plasma passivation leads to a better passivation of grain boundaries than of intra-grain defects, although a possible difference in dislocation density can also have an influence. The luminescence peak at around 0.960 eV stays prominently present after hydrogen plasma passivation. Luminescence at 0.969 eV can be linked to a centre consisting of two carbon atoms and one unique silicon atom. SIMS measurements (see FIG. 5) having indeed shown that carbon was present in the samples.

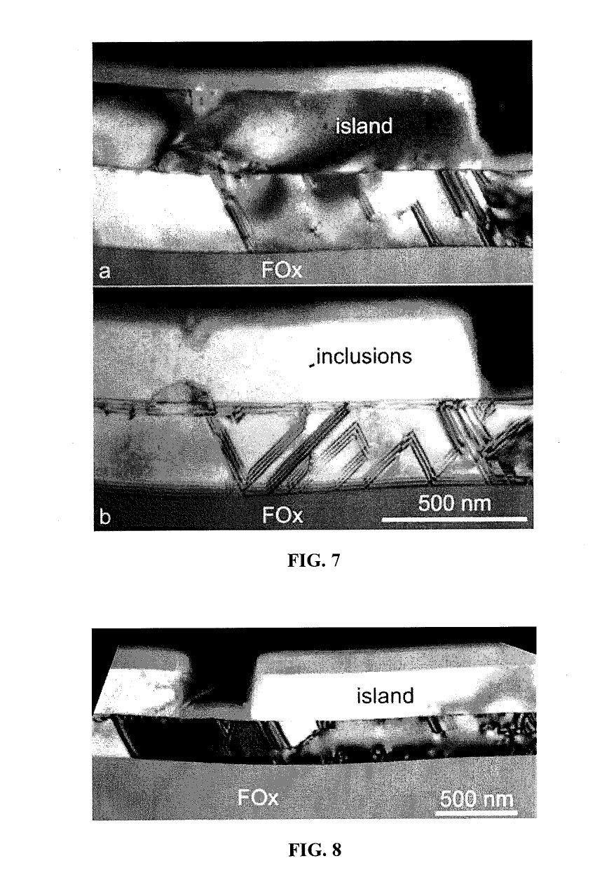

Both EBIC and PL measurements show that some active defects are still present after hydrogen plasma passivation. Understanding the origin of the defects is needed to further reduce the intra-grain defect density. Cross-section TEM was used to investigate the origin of the intra-grain defects observed. FIG. 7 and FIG. 8 show cross section TEM images of AIC seed layers after Al removal and before epitaxial deposition. In-depth crystallographic defect analysis was performed in a Tecnai F30 300 kV transmission electron microscope. Sample preparation for TEM was done with a focused ion beam (FIB) by internal lift-out in a Strata400S dual-beam FIB/SEM instrument. High angle annular dark field scanning TEM (HAADF-STEM) and energy dispersive X-ray spectroscopy (EDS) analyses were performed in addition to TEM. The substrate was in both cases FOx covered alumina. The crystallization temperature of the AIC seed layers was 500° C. and 420° C. for FIG. 7 and FIG. 8 respectively. FIG. 7 shows two TEM images of the same area, each under a slightly different sample tilt to distinguish better the different features present. For both seed layers the islands, which are crystalline, have a different orientation compared to the seed layer below. Inclusions were present in the islands that were not observed in the seed layer. The nature of the inclusions could not be determined. No contamination (e.g. Al) could be detected by Energy Dispersive Spectroscopy X-ray analysis and they are also not revealed in HAADF-STEM mode. This suggests that the average atomic number is (almost) the same as for regular silicon. For both crystallization temperatures, extended defects were clearly present in the seed layer. In the seed layer of FIG. 7, stacking faults on two sets of inclined {111} planes are visible. The grain normal to the substrate was in this case close to [001]. The AIC seed layer crystallized at a temperature of 420° C. (FIG. 8) shows stacking faults as well as twins. In this sample a defect with a shallow angle compared to the substrate was found. The defects under a steep angle to the substrate stop at the shallow angle defects. In other parts of the seed layer, not shown here, dislocations were also found. These images show that intra-grain defects were already present in the seed layer after crystallization and before any high temperature processing (such as e.g. epitaxial layer growth) is performed on the seed layers.

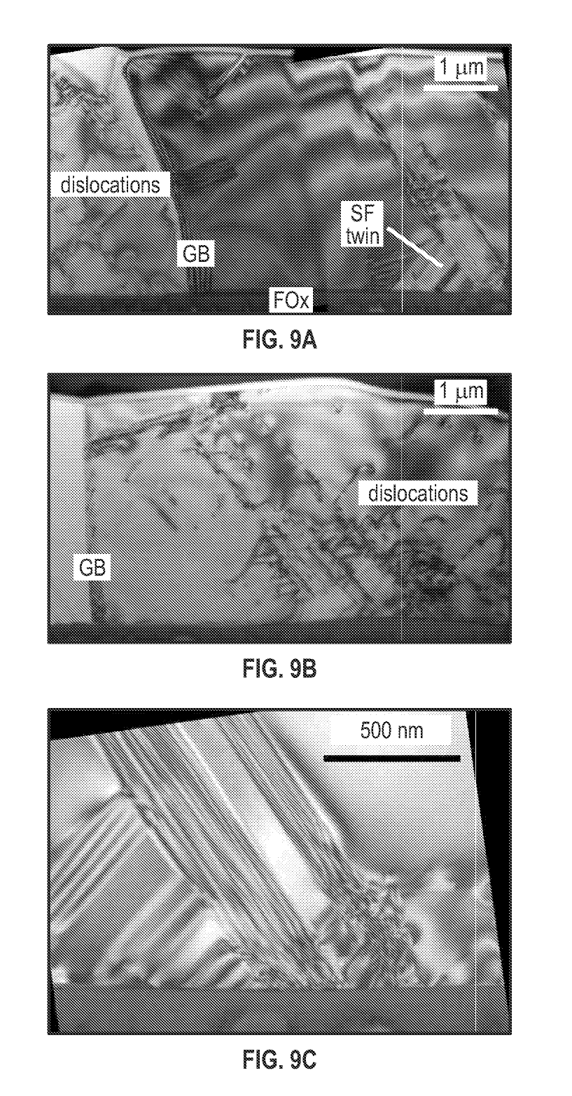

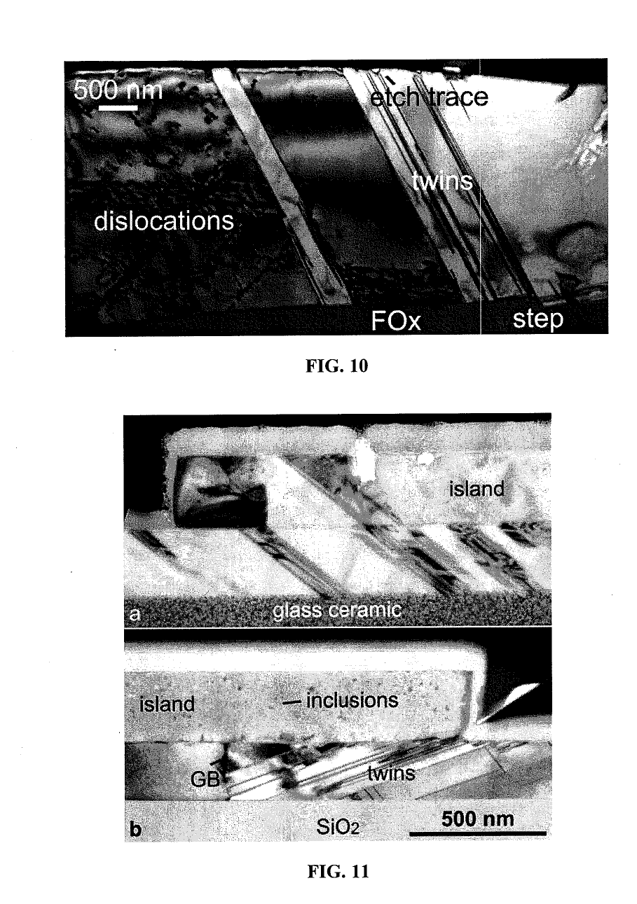

To correlate the intra-grain defects present in the seed layers with those observed in the epitaxial layers grown on top of the seed layers, cross section TEM images were also made after epitaxial growth. FIGS. 9 and 10 show polycrystalline silicon layers (˜3.5 μm thick) grown on seed layers similar to the ones shown in FIGS. 7 and 8 (crystallization temperatures of 500 and 420° C. respectively). Before the epitaxial growth the islands were removed by reactive ion etching. The specimens were oriented in the TEM to obtain optimum contrast on the lattice defects resulting in different sample tilts in FIGS. 9(a) and 9(b). FIGS. 9(a) and 9(b) represent three different grains next to one another. The interface between the seed layer and the epitaxial layer cannot be distinguished, indicating the good quality of the epitaxial growth. However the layer is not free of lattice defects. In the left grain of FIG. 9(a) many dislocations are visible. In the right grain of FIG. 9(a) and the grain in FIG. 9(b), stacking faults and twins running through the whole layer can be distinguished as well as dislocations. The latter are isolated or networked nearly in {111} planes. FIG. 9(c) is a more detailed TEM image of the stacking faults found in the right grain of FIG. 9(a) at the substrate—polycrystalline silicon layer interface. It shows that the stacking faults are starting at the FOx—polycrystalline silicon interface and not at the surface of the original seed layer (which was approximately 200 nm thick). Hence the defects run completely through the AIC seed layer and continue in the epitaxial layer. All samples investigated by TEM after epitaxial growth show a similar behavior: most of the stacking faults/twins and dislocations have their starting point in the seed layer.

The polycrystalline silicon layer of FIG. 10 was slightly defect etched before TEM sample preparation. This allowed a better alignment of the TEM sample with the crystallographic directions in the grains during preparation and thus allowed the relation between the defect etched marks found by SEM and the nature of the defects to be investigated. The TEM samples were cut from the original samples by FIB perpendicular to some etched lines. The trace of these lines can be seen at the top of FIG. 10 as small dips in the surface. At the middle left side and lower middle part of FIG. 10, several {111} planes are seen nearly edge-on (i.e. plane nearly parallel with the electron beam) which contain a high density of dislocations. The crystal orientation of the grain on both sides of these defected planes is equal, showing that these are intra-grain defects. Some of these defected planes run from the interface of the FOx layer through the seed layer into the epitaxial layer. Besides dislocations, many twins or nano-twinned regions which also run through the whole layer were present. The grain of FIG. 10 is seen along a [110] direction such that the regions with darker contrast have the [001] direction nearly vertical to the substrate, i.e. along the growth direction, whereas the regions with the brighter contrast are twinned on the (111) plane and have therefore a [221] direction along the growth direction. This situation corresponds with the narrow banded regions described before and observed in the IPF-EBSD maps (FIG. 1) and the SE channeling contrast image (FIG. 4(a)). The twins are ending in the traces made by the defect etching. Nanometer-spaced twin boundaries only give rise to a single etch dip on the surface. Stacking faults were not observed in this grain but would give rise to similar etch dips. Therefore it can be concluded that part of the lines found by defect etching are related to twin boundaries or multiple nanotwins close together and not only to stacking faults. This observation supports the previous conclusion that some of the electrically active defects that appear as lines can be associated with twins. No perpendicular twin boundaries were found by EBSD, whereas after defect etching perpendicular lines are commonly observed (FIG. 3). This was explained by the fact that both stacking faults and twins can give rise to defect etched lines. Stacking faults however could not be detected by EBSD as the grain orientation on both sides was equal. Moreover, not all twin boundaries present could be revealed by EBSD due to the limited lateral resolution.

In the right part of the FOx layer in FIG. 10 a step is visible. The step results from etching of the oxide through holes in the seed layer during a hydrogen bake performed before the epitaxial growth. Crystalline silicon with the same orientation as the grain above it is found in the steps. This observation shows that high temperature-APCVD epitaxy closes the holes in the seed layer without forming a fine grained region. Detailed TEM images of the step show the presence of twin planes with shallow angles to the substrate. Such twins are also present in the neighboring seed layer.

From these experiments it can be concluded that the extended intra-grain defects in the polycrystalline silicon layers are already present in the seed layer before epitaxial growth, and that after growth most of the extended intra-grain defects run through both the AIC seed layer region and the epitaxial layer. This shows that the AIC seed layer is the major source of the defects found in the epitaxial layer and not the seed layer-epitaxial layer interface or the epitaxial layer itself.

The TEM study clearly points towards the seed layer as the source for most of the intra-grain defects in the final polycrystalline silicon layers. A microscopic parameter which triggers the defect formation during the AIC process was not found. Since seed layers crystallized at different temperatures show similar intra-grain defect densities, the crystallization temperature seems not to have a large influence on the defect formation (at least not in the temperature range between 420° C. and 550° C.).

All polycrystalline silicon layers described above were made on FOx-covered alumina substrates. However, the surface roughness of such substrates is still substantially larger than that of glass substrates.

Investigation of the Effect on Intra-Grain Defect Formation of the Surface Roughness of the Substrate and of the Large Difference in Coefficient of Thermal Expansion (CTE) Between the Alumina (˜8 10⁻⁶ K⁻¹) and Both the Silicon (˜4 10⁻⁶ K⁻¹) and Aluminum (˜27 10⁻⁶ K⁻¹) Layers:

AIC seed layer formation was also studied on oxidized silicon wafers and on glass ceramic substrates. Both had a surface RMS roughness of ca. 1 to 2 nm or less, which was much lower than the RMS roughness of 45 nm for a FOx-covered alumina substrate. The CTE of the glass ceramic used was ca. 3.5-4 10⁻⁶ K⁻¹ which was relatively close to that of silicon. AIC seed layers on these two types of substrates had a similar morphology to those formed on alumina covered with FOx. FIG. 11 shows cross section TEM images of seed layers on both types of substrates. Despite a CTE closer to that of silicon and a lower surface roughness compared to the FOx covered alumina substrates, intra-grain defects such as stacking faults and twins were again visible. The intra-grain defect creation was therefore not only linked to the use of (FOx smoothed) alumina as foreign substrate.

AIC seed layers made on different substrates were also investigated with Raman spectroscopy. In general for monocrystalline silicon, compressive stress results in an increase of the Raman frequency (w), while tensile stress results in a decrease of the Raman frequency. However, due to a relative broad grain size distribution and the presence of a broad range of orientations in the layers under investigation the relationship between the relative Raman shift (Δω=ωₛₐₘₚₗₑ−ω_{ref}) and the strain tensor components was more complicated. For poly-silicon the peak was shifted towards a lower frequency and was asymmetrically broadened towards the low energy side. Therefore a Raman frequency larger than that of unstrained monocrystalline silicon could be linked to compressive stress, whereas for the samples analyzed here the presence of tensile stress remained uncertain. Owing to the polycrystalline nature of the samples a quantification of the compressive stress could not be given.

Micro Raman measurements were performed with a Jobin-Yvon U100 system in backscattering configuration using the 457.9 nm line of an Argon ion laser. Linescan measurements were performed with a laser spot size of 1 μm² and a typical stepsize of 0.1 μm. The calibration was carried out with a silicon reference wafer. Table 2 shows the average Raman shift measured for AIC seed layers made on different substrates. The measurements were performed at room temperature, after cooling down from the crystallization temperature (500° C.) to room temperature (22° C.) and after removing the aluminum layer. The measurements were performed in an area without holes in the AIC seed layer and without the presence of silicon islands. The fluctuation in Raman shift could—in addition to a real difference in stress—also be due to the presence of different grains with e.g. changing orientation or grain size.

A negative Raman shift was found for both the AIC seed layer made on a glass ceramic substrate and on an oxidized silicon wafer. Both substrates have a CTE close to the one of silicon. Due to the intrinsic Raman shift related to the polycrystalline nature of the material it is not sure if compressive or tensile stress is present in these layers. However, a positive Raman shift, and therefore compressive stress, was found for AIC seed layers made on FOx covered alumina substrates. The presence of compressive stress can be explained by the larger CTE of alumina compared to silicon and the cooling down from 500° C. to room temperature after the AIC process.

The observation that intra-grain defects were present in AIC seed layers made on all three tested substrates, but that a different stress was present after cooling down to room temperature suggests that defect formation was not (only) due to cooling down from the AIC crystallization temperature to room temperature.

TABLE 2

| Δω (cm⁻¹) | Alumina/FOx | Glass ceramic | Oxidized wafer |
|---|---|---|---|
| AIC seed layer | 1.22 ± 0.07 | −0.25 ± 0.05 | −0.21 ± 0.11 |

Calculations of process induced stress were performed for a structure comprising an alumina substrate, an aluminum layer and an amorphous silicon layer in which it was assumed that the aluminum layer and the amorphous silicon layer were deposited at a temperature of 20° C. and in which the structure was assumed to be heated up to 500° C. (simulating the temperature cycle of a prior art AIC process). The induced stress in the different layers resulting from heating to 500° C. was calculated before aluminum induced crystallization (i.e. before layer exchange and before conversion of amorphous silicon into polycrystalline silicon). The calculations were based on elasticity theory with the assumption of force equilibrium and compatibility of displacement. The difference in CTE between the different materials was taken into account. Table 3 gives an overview of the values used for the thickness, elastic modulus, poisons ratio and CTE for the different layers in the structure. The stress as calculated for the different layers after heating to 500° C. is shown in Table 4. These calculations suggest that the presence of a large compressive stress (−) in the aluminum layer and a large tensile stress (+) in the silicon layer after heating the stack of layers to 500° C. This stress may be related to the difference in CTE between the substrate, the aluminum layer and the amorphous silicon layer. When performing an AIC process, the nucleation of silicon grains starts in the aluminum layer. This means that the growing silicon grains are formed in a stressed layer, which may be an important origin for intra-grain defects in the resulting seed layer.

TABLE 3

| | Alumina | Aluminum | Silicon |
|---|---|---|---|
| Thickness [μm] | 508 | 0.2 | 0.23 |
| Elastic Modulus [MPa] | 370000 | 68000 | 112400 |
| Poisons ratio | 0.22 | 0.3 | 0.28 |
| Expansion coefficient | 8 | 27 | 4 |
| CTE [10⁻⁶/° C.] | | | |

TABLE 4

| | Stress [MPa] |
|---|---|
| Substrate | −0.5 |
| Aluminum | −908.7 |
| Silicon | 271.9 |

Stress may also play an important role in the formation of intra-grain defects in the AIC seed layer. Another embodiment relates to a method for forming a good seed layer based on aluminum induced crystallization, wherein the seed layer has an intra-grain defect density that is substantially lower than the intra-grain defect density of prior art AIC based seed layers. This allows epitaxial growth of a polycrystalline silicon layer on the seed layer, wherein the density of intra-grain defects in the polycrystalline silicon layer (epitaxial layer) is substantially reduced as compared to the density of intra-grain defects in epitaxial layers grown on prior art AIC seed layers.

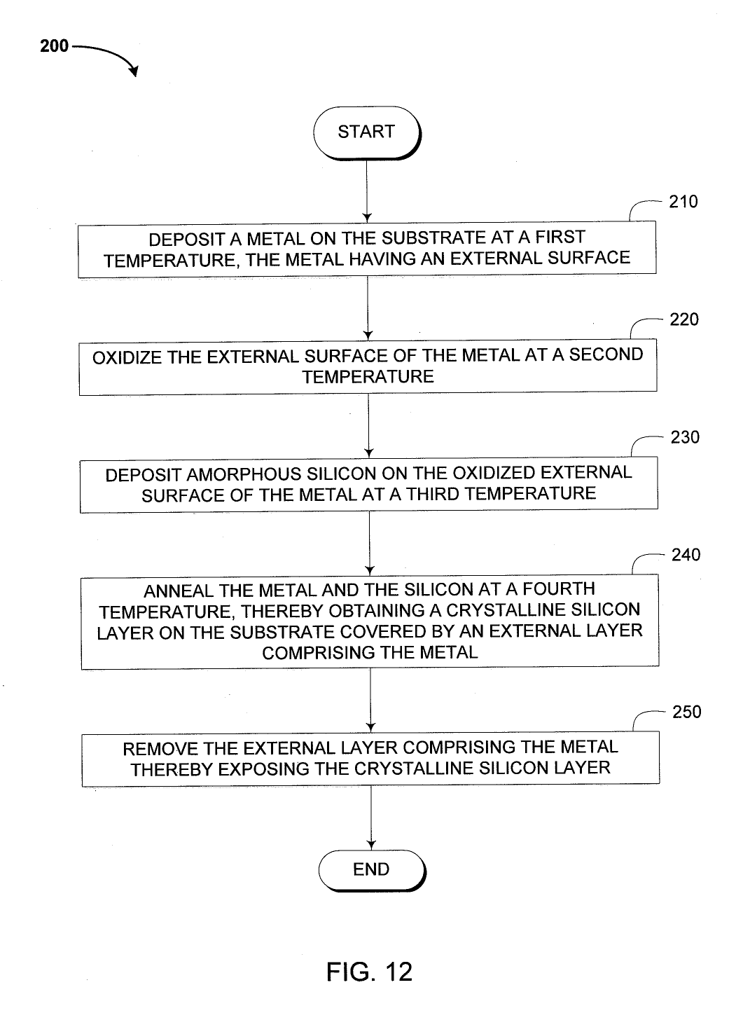

FIG. 12 shows a flowchart of one embodiment of a method of forming a crystalline silicon layer on a substrate. In one embodiment, the method includes performing a metal induced crystallization process. The process 200 includes, at a block 210, depositing a metal on the substrate at a first temperature, the metal having an external surface. Moving to a block 220, the method may further include oxidizing the external surface of the metal at a second temperature. Next at a block 230, the method may further include depositing amorphous silicon on the oxidized external surface of the metal at a third temperature. Moving to a block 240, the method may further include annealing the metal and the silicon at a fourth temperature, thereby obtaining a crystalline silicon layer on the substrate covered by an external layer comprising the metal. Next at a block 250, the method may further include removing the external layer comprising the metal thereby exposing the crystalline silicon layer. In one embodiment, at least the first temperature and the fourth temperature may not be lower than about 200° C. In one embodiment, the first, third and fourth temperatures may be substantially identical. In one embodiment, each of the first, second, third, and fourth temperature may be lower than a metal/silicon eutectic temperature

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention.

What is claimed is:

1. A method of forming a crystalline silicon layer on a substrate, the method comprising performing a metal induced crystallization process, the process comprising:
depositing a metal on the substrate at a first temperature, the metal having an external surface;
oxidizing the external surface of the metal at a second temperature;
depositing amorphous silicon on the oxidized external surface of the metal at a third temperature;
annealing the metal and the silicon at a fourth temperature, thereby obtaining a crystalline silicon layer on the substrate covered by an external layer comprising the metal; and
removing the external layer comprising the metal thereby exposing the crystalline silicon layer,
wherein at least the first temperature and the fourth temperature are not lower than about 200° C., wherein the first, third and fourth temperatures are substantially identical, wherein each of the first, second, third, and fourth temperature is lower than a metal/silicon eutectic temperature.

2. The method according to claim 1, wherein the first, second, third and fourth temperatures are substantially identical.

3. The method according to claim 1, wherein the substrate comprises at least one material selected from the group of a ceramic material, glass, a glass-ceramic material, mullite, alumina, and silicon nitride.

4. The method according to claim 1, wherein the crystalline silicon layer is subject to hydrogen plasma passivation.

5. The method according to claim 1, wherein the method further comprises epitaxially growing a polycrystalline silicon layer on the crystalline silicon layer.

6. The method according to claim 1, wherein the metal is aluminum.

7. The method according to claim 6, wherein the third temperature is in the range between about 200° C. and 550° C., wherein the deposition of the amorphous silicon layer is directly followed by the annealing process for realizing aluminum induced crystallization.

8. The method according to claim 7, wherein the duration of the annealing process at the fourth temperature is sufficiently long for the amorphous silicon layer to be converted into a polycrystalline silicon layer on the substrate.

9. The method according to claim 6, wherein the second temperature and the third temperature are in the temperature range between about 18° C. and 550° C.

10. The method according to claim 6, wherein the first temperature and the fourth temperature are in the temperature range between about 200° C. and 550° C.

11. The method according to claim 6, wherein the first temperature and the fourth temperature are in the temperature range between about 420° C. and 550° C.

12. A crystalline silicon layer formed by the method according to claim 1.

13. A crystalline silicon layer manufactured by a method for forming a crystalline silicon layer on a substrate, the method comprising:
depositing a metal on the substrate at a first temperature, the metal having an external surface;
oxidizing the external surface of the metal at a second temperature;
depositing amorphous silicon on the oxidized external surface of the metal at a third temperature;
annealing the metal and the silicon at a fourth temperature, thereby obtaining a crystalline silicon layer on the substrate covered by an external layer comprising the metal; and
removing the external layer comprising the metal thereby exposing the crystalline silicon layer, wherein at least the first temperature and the fourth temperature are not lower than 200° C.

14. The crystalline silicon layer according to claim 13, wherein the first, third and fourth temperatures are substantially identical.

15. The crystalline silicon layer according to claim 13, wherein each of the first, second, third, and fourth temperature is lower than a metal/silicon eutectic temperature.
